(19) United States
(12) Patent Application Publication
(10) Pub. No.: US 2018/0178429 A1
(43) Pub. Date: Jun. 28, 2018

(54) MOLDING APPARATUS

(71) Applicant: Siliconware Precision Industries Co., Ltd., Taichung City (TW)

(72) Inventors: Yuan-Hong Sun, Taichung City (TW); Wei-Sheng Lin, Taichung City (TW); Yu-Sheng Chang, Taichung City (TW); Yu-Hsiang Lee, Taichung City (TW); Chien-Chih Chen, Taichung City (TW); An-Fu Lee, Taichung City (TW)

(21) Appl. No.: 15/496,262

(22) Filed: Apr. 25, 2017

(30) Foreign Application Priority Data
Dec. 22, 2016 (TW) 105142680

(51) Int. Cl. B29C 45/76; B29C 70/70; B29C 45/14; H01L 21/67

(52) U.S. Cl. CPC B29C 45/7653; B29C 70/70; B29L 2031/3406; H01L 21/67126; H01L 21/67253; B29C 45/14819

(57) ABSTRACT

A molding apparatus is provided, including a mold, a measurement device configured for sensing a state of the mold, and a calibration device electrically connected to the measurement device and configured for determining a state of a sensing function of the measurement device. Therefore, the problem that the measurement device is too old to accurately sense the state of the mold is solved.

### BACKGROUND

### 1. Technical Field

The disclosure relates to semiconductor packaging apparatuses, and, more particularly, to a molding apparatus.

### 2. Description of Related Art

A packaging structure using a leadframe or a substrate as a carrier is typically formed by connecting a chip to the leadframe or the substrate through wires or bumps and encapsulating the chip and the wires (or the bumps) with an encapsulant by a molding packaging process to prevent moisture from getting therein.

FIGS. 1A and 1B are schematic diagrams illustrating a molding apparatus 1 during a molding process according to the prior art. The molding apparatus 1 includes a support structure 14, a mold 10 provided on the support structure 14, a measurement device 11, and a filler 13. The mold 10 includes a first mold body 10a and a second mold body 10b, and the filler 13 is provided on the second mold body 10b. The measurement device 11 includes a sensor 110 provided on the support structure 14 and a controller 111 electrically connected with the sensor 110. The controller 111 is used for controlling the sensor 110 and processing data received by the sensors 110.

First, an object to be packaged (not shown) is disposed on the second mold body 10b shown in FIG. 1A, and a preheated half-melted resin (i.e., a molding compound/encapsulant) is filled in the filler 13.

Then, a motor (not shown) provides a force f to move the first mold body 10a downwards until it joins with the second mold body 10b, such as that shown in FIG. 1B, thereby forming a receiving space S between the first and the second mold bodies 10a and 10b and the mold 10 being in a closed state with the object to be packaged within the receiving space S.

In order to accurately provide the force f of the motor to ensure that the first and second mold bodies 10a and 10b are effectively clamped after the mold 10 is closed, the measurement device 11 measures the force f (as described below) and converts the measurement of the force f into a voltage value so as to determine if the mold 10 is properly in the closed state. More specifically, the sensor 110 is a pressure sensor. When a metal string inside the pressure sensor receives a force (that is, the force f transmitted to the sensor 110 via the support structure 14), the length and the cross-sectional area of the metal string will change, which in turn will cause a change in the resistance of the metal string. Therefore, by knowing the relationship between the resistance and the voltage, and in conjunction with the use of a voltage amplifier, the pressure (i.e., the force can be detected.

After that the mold 10 is properly sealed is confirmed, a molding process can begin by filling the molding compound (e.g., half-melted resin) into the receiving space S. The measurement device 11 keeps measuring the joining state of the mold 10.

Once the molding compound is hardened, the mold 10 is opened as shown in FIG. 1C, and the product (i.e., a packaged object) can be retrieved.

However, in the molding apparatus 1 according to the prior art, fatigue or aging may occur in the metal string inside the sensor 110 over time, such that the initial voltage of the sensor 110 may not be correct, which leads to bias in the voltage value outputted and misjudgment in an automatic warning system (not shown) of the molding apparatus 1. As a result, the molding apparatus 1 may abruptly come to a halt during the molding packaging process, leaving the packaging of an object 8 (shown in FIG. 1D) unfinished (e.g., the receiving space S is not fully filled with the molding compound or the molding compound is not hardened yet), resulting in the unfinished object 8 being scrapped.

Therefore, there is a need for a solution that addresses the aforementioned issues in the prior art.

### SUMMARY

In view of the aforementioned shortcomings of the prior art, the disclosure provides a molding apparatus, which may include a mold, a measurement device configured for sensing if a state of the mold is normal, and a calibrating device electrically connected with the measurement device and configured for determining a state of a sensing function of the measurement device.

In an embodiment, the mold may include a first mold body and a second mold body, which can be joined together by forces, and a receiving space formed between the first mold body and the second mold body. In another embodiment, the measurement device may measure and convert the forces into voltage signals to check the joining state of the first mold body and the second mold body.

In an embodiment, the measurement device may include a sensor and a controller for measuring the forces received by the mold and converting the forces into voltage signals.

In an embodiment, the calibrating device may include a detecting and collecting unit and a data processor. The detecting and collecting unit is used for detecting and collecting voltage signals of the measurement device. The data processor determines the state of the sensing function of the measurement device based on the voltage signals.

In an embodiment, the calibrating device measures a voltage (e.g., an initial voltage) of the measurement device to determine/check the state of the sensing function of the measurement device based on an internally set voltage value. In another embodiment, the initial voltage, if less than or equal to 0.3 volt, indicates that the measurement device is normal. In yet another embodiment, the initial voltage, if greater than 0.3 volt, indicates that the measurement device is abnormal.

In an embodiment, the molding apparatus may further include a filler in communication with the internal part of the mold for filling the mold with a molding compound.

In an embodiment, the molding apparatus may further include an actuating device connected with the mold to actuate the mold.

It can be known from the above that the molding apparatus according to the disclosure is able to determine the state of the sensing function of the measurement device by using the calibrating device in order to prevent errors in the measured voltage values due to aging of the measurement device and further prevent the molding apparatus from halting the molding process due to abnormal conditions. Therefore, compared to the prior art, the molding apparatus according to the disclosure is able to prevent objects being scrapped due to unfinished packaging.

### BRIEF DESCRIPTION OF THE DRAWINGS

The disclosure can be more fully understood by reading the following detailed description of the embodiments, with reference made to the accompanying drawings, wherein:

FIGS. 1A-1C are schematic diagrams illustrating the operation of a molding apparatus according to the prior art;

FIG. 1D is a schematic diagram illustrating the abnormal operation of the molding apparatus according to the prior art;

FIGS. 2A and 2B are schematic diagrams illustrating the operation of a molding apparatus according to the disclosure;

FIG. 3 is a schematic diagram illustrating a local arrangement of FIG. 2; and

FIG. 4 is a schematic diagram illustrating an operation method of a molding apparatus according to the disclosure.

### DETAILED DESCRIPTION OF THE EMBODIMENTS

The disclosure is described by the following specific embodiments. Those with ordinary skills in the arts can readily understand other advantages and functions of the disclosure after reading the disclosure of this specification. The disclosure may also be practiced or applied with other different implementations. Based on different contexts and applications, the various details in this specification can be modified and changed without departing from the spirit of the disclosure.

It should be noted that the structures, ratios, sizes shown in the drawings appended to this specification are to be construed in conjunction with the disclosure of this specification in order to facilitate understanding of those skilled in the art. They are not meant, in any ways, to limit the implementations of the disclosure, and therefore have no substantial technical meaning. Without affecting the effects created and objectives achieved by the disclosure, any modifications, changes or adjustments to the structures, ratio relationships or sizes, are to be construed as fall within the range covered by the technical contents disclosed herein. Meanwhile, terms, such as “up”, “down”, “bottom”, “first”, “second”, “a” and the like, are for illustrative purposes only, and are not meant to limit the range implementable by the disclosure. Any changes or adjustments made to their relative relationships, without modifying the substantial technical contents, are also to be construed as within the range implementable by the disclosure.

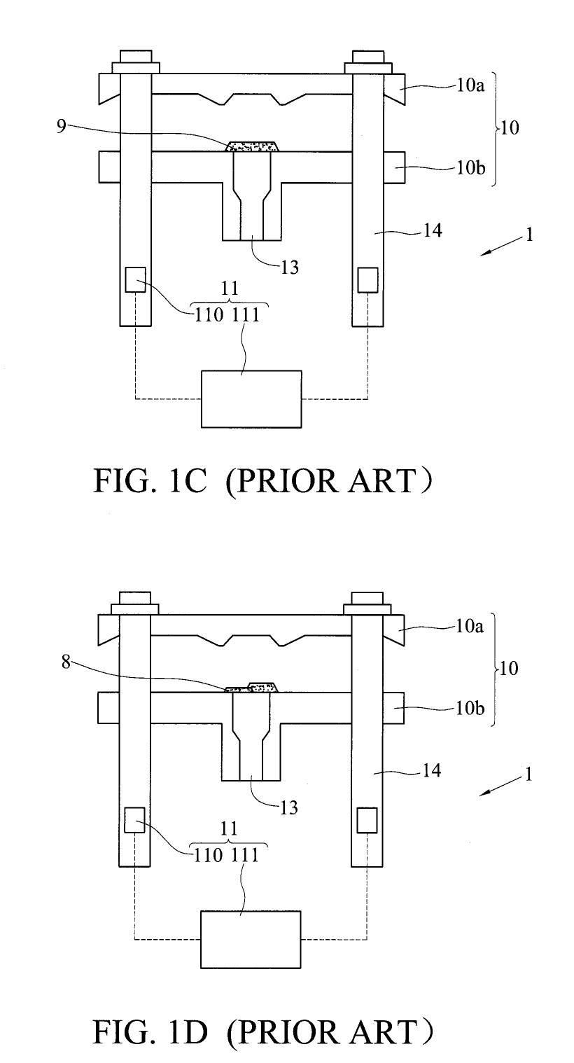

FIGS. 2A and 2B are schematic diagrams illustrating a molding apparatus 2 in accordance with the disclosure. The molding apparatus 2 includes a mold 20, a measurement device 21 (the arranged locations of elements of the measurement device 21 are indicated by reference numbers but their detailed structures are not shown) for sensing a state of the mold 20, and a calibrating device 22 electrically connected with the measurement device 21 (its arranged location is indicated by the reference number but its detailed structure is not shown).

The mold 20 at a closed state during a molding process forms at least one receiving space S, as shown in FIG. 2B.

In an embodiment, the mold 20 includes a first mold body 20a (e.g., an upper mold) and a second mold body 20b (e.g., a lower mold), and the first mold body 20a and the second mold body 20b are joined together by a force F (as shown in FIG. 2A) to thus form the receiving space S between the first and the second mold bodies 20a and 20b.

The molding apparatus 2 further includes a filler 23, which is communication with the internal part of the mold 20 (when it is closed), so as to fill a molding compound (not shown) into the receiving space S of the mold 20 during the molding process. For example, the filler 23 is provided on the second mold body 20b.

The molding apparatus 2 further includes an actuating device 24 connected with the mold 20 for providing forces P and F to the mold 20. In an embodiment, the actuating device 24 includes a power unit 240 (such as a motor, its arranged location is indicated by the reference number, but its detailed structure is not shown) for driving the mold 20, and a supporting structure 241 (such as tracks, their shapes are roughly shown and indicated by the reference number but their detailed structures are not shown) for supporting the mold 20 thereon. Therefore, the first mold body 20a and/or the second mold body 20b can move with respect to the supporting structure 241 (for example, along the direction of at least one force F as shown in FIG. 2A).

The measurement device 21 is used for measuring the joining state of the mold 20 to determine if the mold 20 is properly sealed.

In an embodiment, the measurement device 21 measures the forces P and F to check the joining state of the mold 20. In another embodiment, the measurement device 21 includes a sensor 210 and a controller 211. In an embodiment, the sensor 210 is a pressure sensor. When a metal string inside a pressure sensor receives a force (for example, when the supporting structure 241 deforms due to actuation, the metal string inside the sensor 210 also deforms and creates a voltage difference), the length and the cross-sectional area of the metal string will change, this in turn will cause a change in the resistance of the metal string. Therefore, by knowing the relationship between the resistance and the voltage, and in conjunction with the use of a voltage amplifier, the pressure (i.e., the forces P and f) can be detected. The controller 211 is used for controlling the sensor 210 and processing voltage signals measured by the sensor 210. Therefore, by analyzing the voltage signals, the controller 211 is able to check the joining state of the mold 20.

The calibrating device 22 is used for determining if the sensing function of the measurement device 21 (e.g., the sensor 210) is working properly.

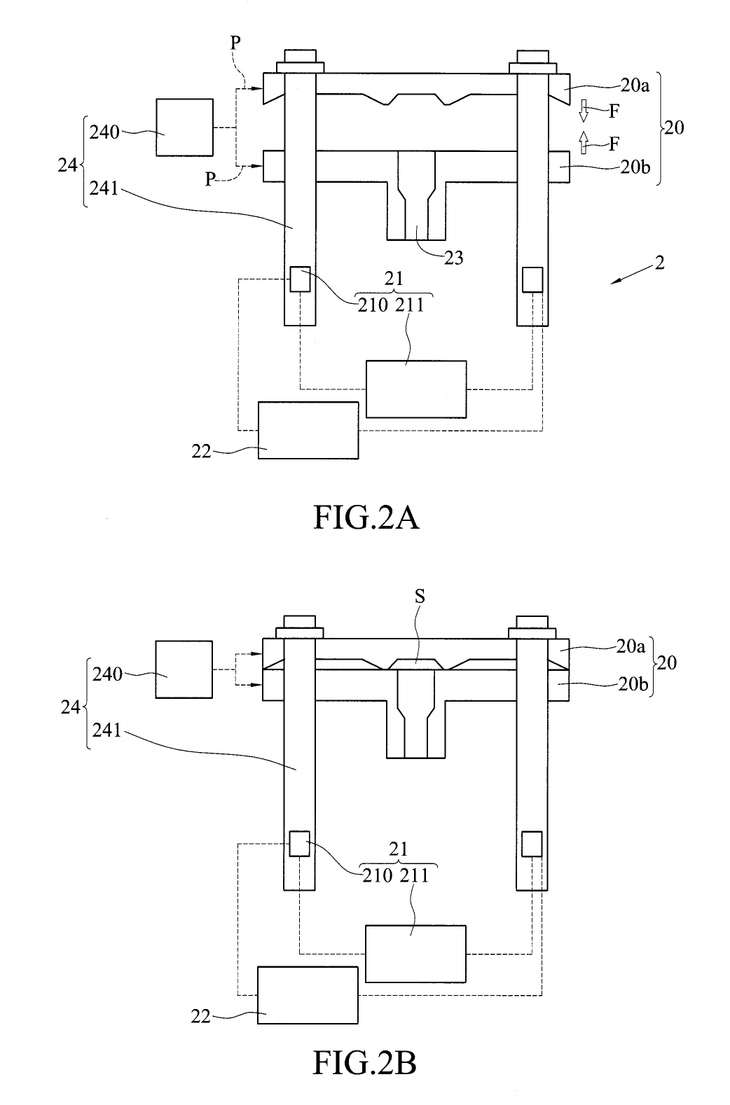

In an embodiment, as shown in FIG. 3, the calibrating device 22 includes a detecting and collecting unit 220 and a data processor 221. The detecting and collecting unit 220 may be, for example, a voltage detector such as a voltmeter for detecting and collecting the voltage signals of the measurement device 21 (e.g., the sensor 210), and the data processor 221 is a computational unit such as a computer for determining the state of the sensing function of the measurement device 21 based on the voltage signals, for example, by analyzing and processing the voltage signals detected by the detecting and collecting unit 220. More specifically, the calibrating device 22 is electrically connected with the actuating unit 240 and the sensor 210. The calibrating device 22 calculates the initial voltage of the sensor 210 to decide if the operation of the actuating unit 240 should proceed.

Therefore, the calibrating device 22 checks the state of the sensing function of the measurement device 21 by measuring the voltage signals.

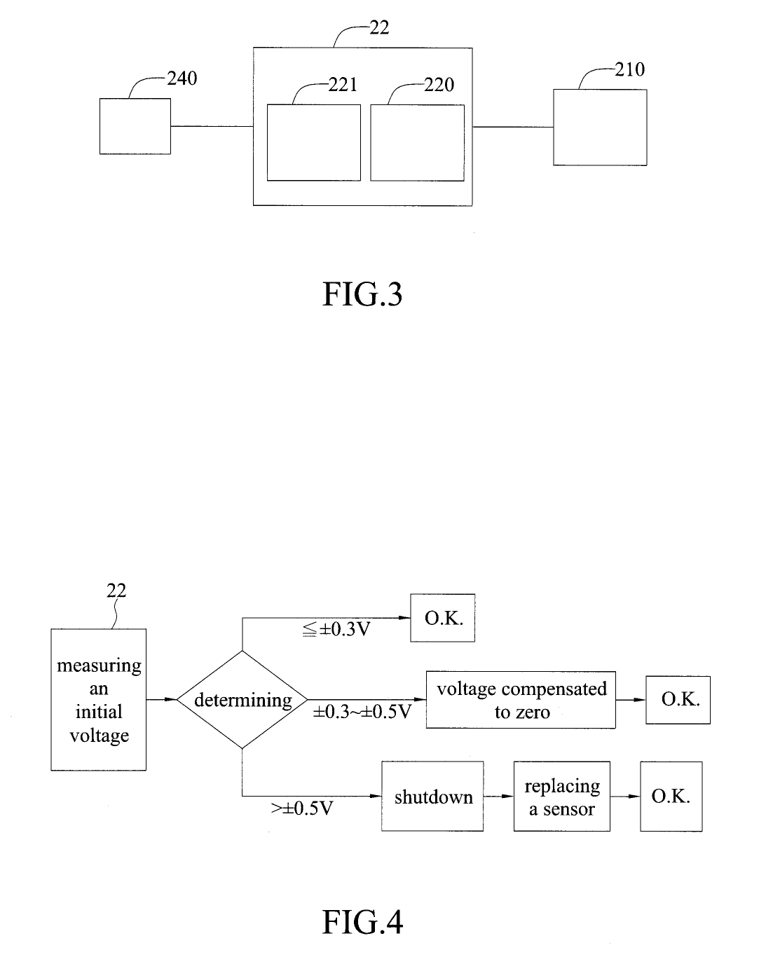

The method for operating the molding apparatus 2 is illustrated in conjunction with FIG. 4.

When the molding apparatus 2 is used, an object to be packaged (not shown) is first disposed on the second mold body 20b shown in FIG. 2A, and a preheated half-melted resin (e.g., a molding compound/encapsulant) is filled into the filler 23. The actuating unit 240 provides an initial force P to the mold 20, and then the calibrating device 22 checks the state of the sensing function of the measurement device 21.

In an embodiment, the calibrating device 22 checks the voltage of the measurement device 21 (for example, an initial voltage of the measurement device 21) and determines if the initial voltage is normal based on an internally set voltage value, that is, checks if the sensing function of the measurement device 21 is normal.

As shown in FIG. 4, if the data processor 221 determines that the initial voltage a detected by the detecting and collecting unit 220 is less than or equal to 0.3 volt (i.e., a≤0.3), the measurement device 21 is functioning properly, and the actuating unit 240 may continue to actuate the first mold body 20a and/or the second mold body 20b. If the initial voltage a is greater than 0.3 volt (i.e., a>0.3), the measurement device 21 is abnormal, and the data processor 221 asks the actuating unit 240 to stop actuating the first mold body 20a and the second mold body 20b (i.e., shutdown).

0.3V<a<0.5V indicates that the sensor 210 requires calibration, such that the voltage after compensation returns to zero (i.e., a≤0.3). For example, when fatigue occurs in the metal string of the sensor 210, the initial voltage a changes, such that the initial voltage a is between 0.3 to 0.5 volt. Thus, the voltage needs to be adjusted back to zero before the actuating unit 240 can start again. Alternatively, if a>0.5V, it indicates that the voltage of the sensor 210 is abnormal, and the actuating unit 240 should stop operating, and the sensor 210 should be replaced.

Once the sensing function of the measurement device 21 is normal, the actuating unit 240 then provides a force F to actuate the first mold body 20a and/or the second mold body 20b with respect to the supporting structure 241 until the first mold body 20a and the second mold body 20b are brought together as shown in FIG. 2B, and the mold 20 is in a closed state ready for the molding process.

The measurement device 21 checks the joining state of the mold 20 to determine if the mold 20 is properly sealed. In an embodiment, the measurement device 21 determines if the mold 20 is properly sealed based on a voltage value converted from the force F measured.

Once the joining state of the mold 20 is normal, the mold 20 is use for the molding process. That is, the receiving space S is filled with molding compound by the filler 23. During this step, the measurement device 21 keeps monitoring the joining state of the mold 20 for use as a reference by an automatic warning system (not shown) of the molding apparatus 2.

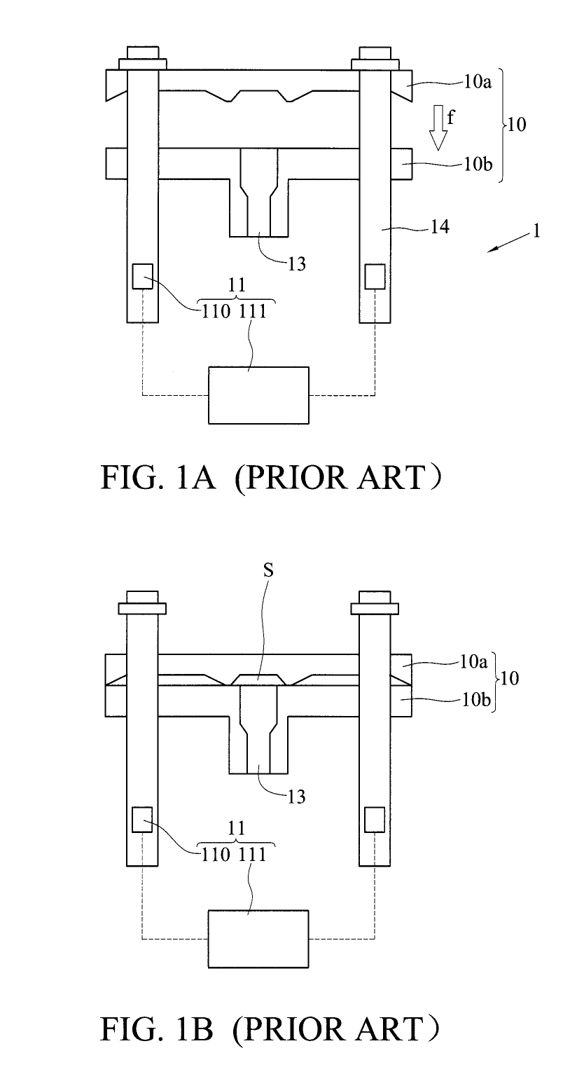

After the molding compound is hardened, the mold 20 is opened (as shown in FIG. 2A), and the product is retrieved (a product 9 shown in FIG. 1C, i.e., a packaged object).

In conclusion, the molding apparatus 2 according to the disclosure is able to determine the state of the sensing function of the measurement device 21 by using the calibrating device 22 to prevent poor sensing results due to aging of the sensor 210 and further prevent the automatic warning system of the molding apparatus 2 from halting the operations of the molding process (e.g., stop the filler 23 from providing the molding compound to the receiving space S or stop hardening of the molding compound etc.) due to abnormal conditions. Therefore, the molding apparatus 2 of the disclosure is able to prevent objects being scrapped due to unfinished packaging.

The above embodiments are only used to illustrate the principles of the disclosure, and should not be construed as to limit the disclosure in any way. The above embodiments can be modified by those with ordinary skill in the art without departing from the scope of the disclosure as defined in the following appended claims.

What is claimed is:

1. A molding apparatus, comprising:
a mold;
a measurement device configured for sensing if a state of the mold is normal; and
a calibrating device electrically connected with the measurement device and configured for determining a state of a sensing function of the measurement device.

2. The molding apparatus as claimed in claim 1, wherein the mold includes a first mold body, a second mold body, and a receiving space formed between the first mold body and the second mold body.

3. The molding apparatus as claimed in claim 2, wherein the measurement device is configured for measuring forces received by the first mold body and the second mold body and converting the forces into voltage signals for checking a joining state of the mold.

4. The molding apparatus as claimed in claim 1, wherein the measurement device includes a sensor and a controller configured for measuring forces received by the mold and converting the forces into voltage signals.

5. The molding apparatus as claimed in claim 1, wherein the calibrating device includes a detecting and collecting unit configured for detecting and collecting voltage signals of the measurement device.

6. The molding apparatus as claimed in claim 5, wherein the calibrating device further includes a data processor configured for determining the state of the sensing function of the measurement device based on the voltage signals.

7. The molding apparatus as claimed in claim 1, wherein the calibrating device is configured for measuring an initial voltage of the measurement device to check the state of the sensing function of the measurement device.

8. The molding apparatus as claimed in claim 6, wherein the initial voltage, if less than or equal to 0.3 volt, indicates that the measurement device is normal.

9. The molding apparatus as claimed in claim 7, wherein the initial voltage, if greater than 0.3 volt, indicates that the measurement device is abnormal.

10. The molding apparatus as claimed in claim 1, further comprising a filler in communication with an internal part of the mold for filling the mold with a molding compound.

11. The molding apparatus as claimed in claim 1, further comprising an actuating device connected with the mold to actuate the mold.
